(19) United States
(12) Patent Application Publication
(10) Pub. No.: US 2024/0224651 A1
(43) Pub. Date: Jul. 4, 2024

(54) DISPLAY DEVICE

(71) Applicant: LG Display Co., Ltd., Seoul (KR)

(72) Inventors: Seongku LEE, Seoul (KR); KangIl KIM, Seoul (KR); Kihyung LEE, Yongin-si (KR); Seongkwang KIM, Goyang-si (KR)

(73) Assignee: LG Display Co., Ltd., Seoul (KR)

(21) Appl. No.: 18/396,790

(22) Filed: Dec. 27, 2023

(30) Foreign Application Priority Data
Dec. 29, 2022 (KR) 10-2022-0189135

(51) Int. Cl. H10K 59/131; H10K 59/121

(52) U.S. Cl. CPC H10K 59/131; H10K 59/1213

(57) ABSTRACT

A display device includes first and second substrates each divided into a display area and a non-display area, a dam disposed between the first and second substrates, a wiring part positioned in the non-display area of the first substrate to overlap the dam, a circuit part provided inside the dam, spaced apart from the wiring part, and positioned in the non-display area of the first substrate, thereby suppressing an operation defect of a gate drive circuit and a screen abnormality defect of a display panel.

### CROSS-REFERENCE TO RELATED APPLICATION

This application claims the priority of Korean Patent Application No. 10-2022-0189135 filed on Dec. 29, 2022, which is hereby incorporated by reference in its entirety.

### BACKGROUND

### Field of the Disclosure

The present disclosure relates to a display device.

### Description of the Background

Display devices, which visually display electrical information signals, are being rapidly developed in accordance with the entry into the information era. Various studies are being continuously conducted to develop a variety of display devices which are thin and lightweight, consume low power, and have improved performance.

As the representative display devices, there may be a liquid crystal display device (LCD), a field emission display device (FED), an electrowetting display device (EWD), an organic light-emitting display device (OLED), and the like.

An electroluminescent display device, as the representative organic light-emitting display device, refers to a display device that autonomously emits light. Unlike a liquid crystal display device, the electroluminescent display device does not require a separate light source and thus may be manufactured as a lightweight, thin display device. In addition, the electroluminescent display device is advantageous in terms of power consumption because the electroluminescent display device operates at a low voltage. Further, the electroluminescent display device is expected to be adopted in various fields because the electroluminescent display device is also excellent in implementation of colors, response speeds, viewing angles, and contrast ratios.

In the electroluminescent display device, a light-emitting element is configured by disposing a plurality of organic layers including light-emitting layers between two electrodes that are an anode and a cathode. For example, when positive holes are injected into the light-emitting layer from the anode and electrons are injected into the light-emitting layer from the cathode, the injected electrons and the injected positive holes are recombined in the light-emitting layer and emit light while producing excitons.

Meanwhile, the electroluminescent display device has a moisture penetration suppressing dam in a bezel area to ensure moisture transmission reliability. In addition, the organic layers, the cathodes, a plurality of organic films, and a plurality of inorganic films are deposited on an upper portion of a substrate, and the organic and inorganic films have tolerances with respect to deposition areas. When the organic layers, the cathodes, the plurality of organic films, and the plurality of inorganic films deviate from the manufacturing tolerances, there may occur various defects.

### SUMMARY

Accordingly, the present disclosure is directed to a display device that substantially obviates one or more of problems due to limitations and disadvantages described above.

More specifically, the present disclosure is to provide a display device that suppresses or prevents fluctuation in line loads of lines of a gate drive circuit.

In addition, the present disclosure is to provide a display device that suppresses or prevents cracks in an insulation layer caused by a dam and a planarization layer.

Further, the present disclosure is to provide a display device that suppresses or prevent a short circuit between a cathode and a line of a gate drive circuit and minimizes a parasitic capacity.

The present disclosure is not limited to the above-mentioned and other features, which are not mentioned above, may be clearly understood by those skilled in the art from the following descriptions.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a display device includes first and second substrates each divided into a display area and a non-display area, a dam disposed between the first and second substrates, a wiring part positioned in the non-display area of the first substrate to overlap the dam, a circuit part provided inside the dam, spaced apart from the wiring part, and positioned in the non-display area of the first substrate and a planarization layer disposed over the first substrate of the circuit part and spaced apart from the dam.

In another aspect of the present disclosure, a display device includes first and second substrates where a display area and a non-display area are defined; a first dam disposed on the second substrate; a wiring part disposed in the non-display area of the first substrate and overlapping the first dam; a circuit part spaced apart from the wiring part, disposed in the non-display area of the first substrate and disposed at a side of the first dam closer to the display area; and one or more second dam disposed in close proximity to the first dam at at least one of the first and second substrates.

According to various aspect of the present disclosure, the fluctuation in line load caused by the parasitic capacity can be suppressed by designing various device structures to avoid the overlap between the cathode and the line of the gate drive circuit.

In addition, the wiring part and the circuit part of the gate drive circuit are separated and disposed, and the planarization layer is designed to correspond to the circuit part, which can suppress a short circuit between the line and the cathode.

Also, a screen abnormality defect of the display panel such as a horizontal dim can be suppressed.

Further, the hydrogen penetration and the cracks in the insulation layer can be suppressed by designing various device structures to avoid the overlap between the planarization layer and the dam. Therefore, it is possible to suppress an operation defect of the gate drive circuit.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a configuration view exemplarily illustrating a display device according to the present disclosure;

FIG. 2 is a plan view schematically illustrating the display device according to the present disclosure;

FIG. 3 is a view illustrating an equivalent circuit of a subpixel of the display device according to the present disclosure;

FIG. 4 is a plan view illustrating a part of a display panel according to a first exemplary aspect of the present disclosure;

FIG. 5 is a cross-sectional view of a subpixel of the display panel in FIG. 4;

FIG. 6 is a view illustrating a part of a cross-sectional structure of the display panel in FIG. 4;

FIG. 7 is a view illustrating a part of a cross-sectional structure of a display panel according to a second exemplary aspect of the present disclosure;

FIG. 8 is a plan view illustrating a part of a display panel according to a third exemplary aspect of the present disclosure; and

FIG. 9 is a view illustrating a part of a cross-sectional structure of a display panel according to a fourth exemplary aspect of the present disclosure.

### DETAILED DESCRIPTION

Advantages and characteristics of the present disclosure and a method of achieving the advantages and characteristics will be clear by referring to exemplary aspects described below in detail together with the accompanying drawings. However, the present disclosure is not limited to the exemplary aspects disclosed herein but will be implemented in various forms. The exemplary aspects are provided by way of example only so that those skilled in the art may fully understand the disclosures of the present disclosure and the scope of the present disclosure.

The shapes, sizes, ratios, angles, numbers, and the like illustrated in the accompanying drawings for describing the exemplary aspects of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only.” Any references to singular may include plural unless expressly stated otherwise.

Components are interpreted to include an ordinary error range even if not expressly stated.

When the position relation between two parts is described using the terms such as “on,” “above.” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various aspects of the present disclosure may be partially or entirely adhered to or combined with each other and may be interlocked and operated in technically various ways, and the aspects may be carried out independently of or in association with each other.

Hereinafter, exemplary aspects of the present disclosure will be described in detail with reference to accompanying drawings.

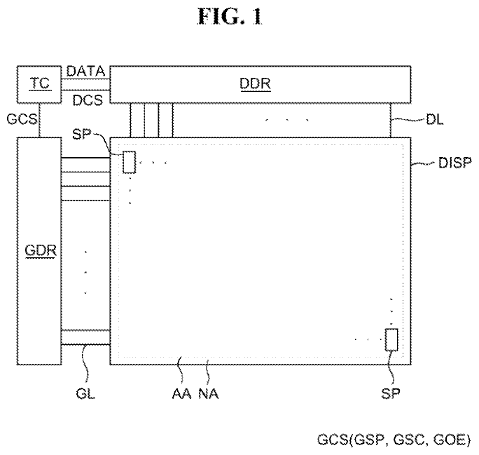

FIG. 1 is a configuration view exemplarily illustrating a display device according to the present disclosure.

Display devices according to exemplary aspects of the present disclosure may include a display device, a lighting device, an electroluminescent display device, and the like. Hereinafter, for convenience of description, the description will be focused on the display device. However, the following description will also be equally applied to various types of display devices such as the lighting device and the electroluminescent display device.

With reference to FIG. 1, the display device according to the exemplary aspects of the present disclosure may include a display panel DISP configured to display images or output light, and a drive circuit configured to operate the display panel DISP.

The display panel DISP includes a plurality of data lines DL and a plurality of gate lines GL. A plurality of subpixels SP defined by the plurality of data lines DL and the plurality of gate lines GL may be arranged in a matrix type.

The plurality of data lines DL and the plurality of gate lines GL of the display panel DISP may be disposed to intersect one another. For example, the plurality of gate lines GL may be arranged in rows or columns, and the plurality of data lines DL may be arranged in columns or rows. Hereinafter, for convenience of description, it is assumed that the plurality of gate lines GL is disposed in rows, and the plurality of data lines DL is disposed in columns.

In addition to the plurality of data lines DL and the plurality of gate lines GL, other types of signal lines may be disposed on the display panel DISP depending on subpixel structures and the like. For example, a drive voltage line, a reference voltage line, a common voltage line, or the like may be further disposed.

The display panel DISP may be one of various types of panels such as a liquid crystal display (LCD) panel and an organic light emitting diode (OLED) panel.

The types of signal lines disposed on the display panel DISP may vary depending on subpixel structures, panel types, and the like. In addition, in the present disclosure, the signal line may conceptually include an electrode to which a signal is applied.

The display panel DISP may include a display area AA that displays images, and a non-display area NA that is disposed at an outer periphery of the display area AA and displays no image. In this case, the non-display area NA is also referred to as a bezel area.

The plurality of subpixels SP for displaying images may be disposed in the display area AA.

A pad part may be disposed in the non-display area NA and electrically connected to a data driver DDR. A plurality of data link lines for connecting the pad part and the plurality of data lines DL may be disposed in the non-display area NA. In this case, the plurality of data link lines may be portions of the plurality of data lines DL that extend to the non-display area NA. Alternatively, the plurality of data link lines may be separate patterns electrically connected to the plurality of data lines DL.

In addition, gate drive-related lines may be disposed in the non-display area NA and transmit voltages, which are required to operate gates, to a gate driver GDR through the pad part electrically connected to the data driver DDR. For example, the gate drive-related lines may include a clock line for transmitting a clock signal, a gate voltage line for transmitting gate voltages VGH and VGL, and a gate drive control signal line for transmitting various types of control signals required to generate scan signals. Unlike the gate line GL disposed in the display area AA, the gate drive-related lines may be disposed in the non-display area NA.

For example, the drive circuit may include the data driver DDR configured to operate the plurality of data lines DL, the gate driver GDR configured to operate the plurality of gate lines GL, and a timing controller TR configured to control the data driver DDR and the gate driver GDR.

As described above, the data driver DDR may operate the plurality of data lines DL by outputting data voltages to the plurality of data lines DL.

In addition, the gate driver GDR may operate the plurality of gate lines GL by outputting scan signals to the plurality of gate lines GL.

For example, the timing controller TR may control driving operations of the data driver DDR and the gate driver GDR by supplying various types of control signals DCS and GCS required for the driving operations of the data driver DDR and the gate driver GDR. In addition, the timing controller TR may supply image data DATA to the data driver DDR.

The timing controller TR may start scanning in accordance with the timing implemented in each frame, output the image data DATA made by converting input image data, which are inputted from the outside, into data signal types used for the data driver DDR, and control data operations at the appropriate time in accordance with the scanning.

For example, to control the data driver DDR and the gate driver GDR, the timing controller TR may receive timing signals such as a vertical synchronizing signal Vsync, a horizontal synchronizing signal Hsync, an input data enable DE signal, and a clock signal CLK from the outside, generate various types of control signals, and output the control signals to the data driver DDR and the gate driver GDR.

For example, to control the gate driver GDR, the timing controller TR may output various types of gate control signals GCS including a gate start pulse GSP, a gate shift clock GSC, a gate output enable signal GOE, and the like.

In addition, to control the data driver DDR, the timing controller TR may output various types of data control signal DCS including a source start pulse SSP, a source sampling clock SSC, a source output enable signal SOE, and the like.

The timing controller TR may be implemented as a component provided separately from the data driver DDR or implemented as an integrated circuit by being integrated with the data driver DDR.

The data driver DDR may receive the image data DATA from the timing controller TR and operate the plurality of data lines DL by supplying data voltages to the plurality of data lines DL. The data driver DDR is also referred to as a source driver.

The data driver DDR may transmit or receive various types of signals to or from the timing controller TR through various types of interfaces.

In addition, the gate driver GDR may sequentially operate the plurality of gate lines GL by sequentially supplying scan signals to the plurality of gate lines GL. In this case, the gate driver GDR is also referred to as a scan driver.

The gate driver GDR may sequentially supply the scan signals with ON-voltages or OFF-voltages to the plurality of gate lines GL under the control of the timing controller TR.

When a particular gate line is opened by the gate driver GDR, the data driver DDR may convert the image data DATA, which are received from the timing controller TR, into analog data voltages and supply the analog data voltages to the plurality of data lines DL.

The data driver DDR may be positioned only at one side of the display panel DISP. In some instances, the data drivers DDR may be positioned at two opposite sides of the display panel DISP in accordance with driving methods, panel designing methods, and the like. For example, the data driver DDR may be positioned at an upper or lower side of the display panel DISP. Alternatively, the data drivers DDR may be positioned at both the upper and lower sides of the display panel DISP.

The gate driver GDR may be positioned only at one side of the display panel DISP. In some instances, the gate drivers GDR may be positioned at two opposite sides of the display panel DISP in accordance with driving methods, panel designing methods, and the like. For example, the gate driver GDR may be positioned at a left or right side of the display panel DISP. Alternatively, the gate drivers GDR may be positioned at the left and right sides of the display panel DISP.

The data driver DDR may be implemented to include one or more source driver integrated circuits SDIC.

For example, the source driver integrated circuits may each include a shift register, a latch circuit, a digital-analog converter DAC, an output buffer, and the like. In some instances, the data driver DDR may further include one or more analog-digital converters ADC.

In addition, for example, the source driver integrated circuit may be connected to a bonding pad of the display panel DISP as a tape-automated bonding (TAB) type or a chip-on-glass (COG) type. Alternatively, the source driver integrated circuit may be disposed directly on the display panel DISP. In some instances, the source driver integrated circuits may be disposed by being integrated on the display panel DISP. In addition, the source driver integrated circuits may each be implemented as a chip-on-film (COF) type. In this case, the source driver integrated circuits may each be mounted on a circuit film and electrically connected to the data line DL of the display panel DISP through a circuit film.

The gate driver GDR may be configured as a plurality of gate drive circuits. In this case, the plurality of gate drive circuits may respectively correspond to the plurality of gate lines GL.

For example, the gate drive circuits may each include a shift register, a level shifter, and the like.

The gate drive circuit may be connected to the bonding pad of the display panel DISP as a tape-automated bonding (TAB) type or a chip-on-glass (COG) type. In addition, the gate drive circuits may each be implemented as a chip-on-film (COF) type. In this case, the gate drive circuits may each be mounted on the circuit film and electrically connected to the gate line GL of the display panel DISP through the circuit film. In addition, the gate drive circuits may each be implemented as a gate-in-panel (GIP) type and embedded in the display panel DISP. For example, the gate drive circuits may each be formed directly on the display panel DISP.

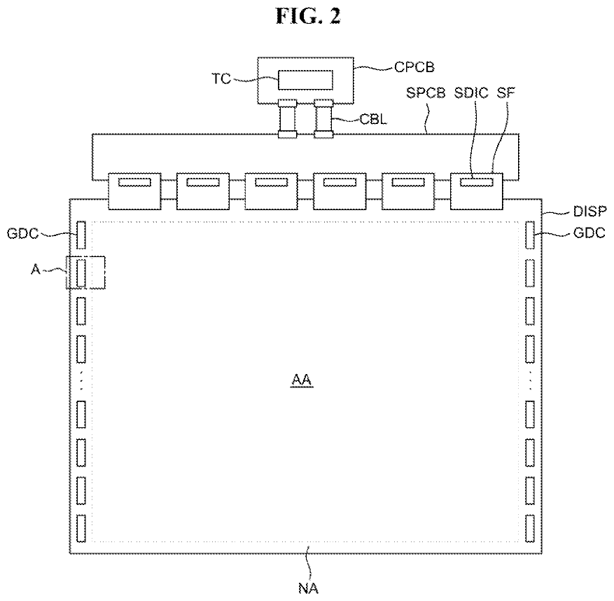

FIG. 2 is a plan view schematically illustrating the display device according to the present disclosure.

With reference to FIG. 2, in the display device according to the exemplary aspects of the present disclosure, the data driver may be implemented as a chip-on-film type among the above-mentioned various types (TAB, COG, COF, etc.), and the gate driver may be implemented as a gate-in-panel (GIP) type among various types (TAB, COG, COF, GIP, etc.). However, the present disclosure is not limited thereto, and various types may be provided.

The data driver may be implemented as one or more source driver integrated circuits SDIC. FIG. 2 illustrates an example in which the data driver is implemented as a plurality of source driver integrated circuits SDIC. However, the present disclosure is not limited thereto.

In case that the data driver is implemented as the COF type, the source driver integrated circuits SDIC, which constitutes the data driver, may be mounted on a source-side circuit film SF.

For example, one side of the source-side circuit film SF may be electrically connected to the pad part (an assembly of pads) disposed in the non-display area NA of the display panel DISP.

In addition, lines for electrically connecting the source driver integrated circuit SDIC and the display panel DISP may be disposed on the source-side circuit film SF.

The display device may include one or more source printed circuit boards SPCB and a control printed circuit board CPCB for mounting control components and various types of electric devices to circuit-connect the plurality of source driver integrated circuits SDIC and the other devices.

For example, the other side of the source-side circuit film SF on which the source driver integrated circuit SDIC is mounted may be connected to the one or more source printed circuit boards SPCB. For example, one side of the source-side circuit film SF on which the source driver integrated circuit SDIC is mounted may be electrically connected to the non-display area NA of the display panel DISP, and the other side of the source-side circuit film SF may be electrically connected to the source printed circuit board SPCB.

In addition, a timing controller TC may be disposed on the control printed circuit board CPCB and control the operation of the data driver and the operation of the gate driver GDR.

A power management integrated circuit PMIC and the like may be further disposed on the control printed circuit board CPCB and supply various types of voltages or electric currents to the display panel DISP, the data driver, the gate driver, and the like or control various types of voltages or electric currents to be supplied.

The source printed circuit board SPCB and the control printed circuit board CPCB may be circuit-connected by at least one connection member CBL.

For example, the connection member CBL may be a flexible printed circuit (FPC), a flexible flat cable (FFC), or the like.

For example, the one or more source printed circuit boards SPCB and the control printed circuit board CPCB may be implemented by being integrated into a single printed circuit board.

In case that the gate driver is implemented as a gate-in-panel (GIP) type, a plurality of gate drive circuits GDC included in the gate driver may be formed directly on the non-display area NA of the display panel DISP.

The gate drive circuit GDC may each output a corresponding scan signal to a corresponding gate line disposed in the display area AA of the display panel DISP.

The plurality of gate drive circuits GDC disposed on the display panel DISP may receive various types of signals (e.g., a clock signal, a high-level gate voltage VGH, a low-level gate voltage VGL, a start signal VST, a reset signal RST, etc.), which are required to generate scan signals, through the gate drive-related lines disposed in the non-display area NA.

The gate drive-related lines disposed in the non-display area NA may be electrically connected to the source-side circuit film SF disposed to be closest to the plurality of gate drive circuits GDC.

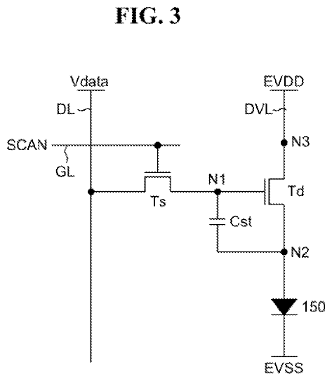

FIG. 3 is a view illustrating an equivalent circuit of a subpixel of the display device according to the present disclosure.

FIG. 3 illustrates an equivalent circuit of a single subpixel in case that the display panel according to the exemplary aspects of the present disclosure is an electroluminescent display panel.

With reference to FIG. 3, the subpixel may each include a light-emitting element 150, a driving transistor Td configured to operate the light-emitting element 150, a switching transistor Ts electrically connected between a first node N1 of the driving transistor Td and the corresponding data line DL, and a storage capacitor Cst electrically connected between the first node N1 and a second node N2 of the driving transistor Td.

The light-emitting element 150 may include an anode, a plurality of organic layers, a cathode, and the like.

As illustrated in FIG. 3, the anode (also referred to as an anode electrode or a pixel electrode) of the light-emitting element 150 may be electrically connected to the second node N2 of the driving transistor Td. In this case, a base voltage EVSS may be applied to a cathode (also referred to as a cathode electrode or a common electrode) of the light-emitting element 150.

The base voltage EVSS may be a ground voltage or a voltage higher or lower than the ground voltage. In addition, the base voltage EVSS may vary depending on a driving state. For example, the base voltage EVSS during an imaging operation may be different from the base voltage EVSS during a sensing operation.

The driving transistor Td may operate the light-emitting element 150 by supplying a drive current to the light-emitting element 150.

The driving transistor Td may include the first node N1, the second node N2, a third node N3, and the like.

The first node N1 may be a gate node of the driving transistor Td and electrically connected to a source node or a drain node of the switching transistor Ts. The second node N2 of the driving transistor Td may be the source node or the drain node and electrically connected to the anode (or the cathode) of the light-emitting element 150. For example, the third node N3 of the driving transistor Td may be the drain node or the source node, a drive voltage EVDD may be applied to the third node N3. The third node N3 may be electrically connected to a drive voltage line DVL that supplies the drive voltage EVDD.

The storage capacitor Cst may be electrically connected between the first node N1 and the second node N2 of the driving transistor Td and maintain, for one frame time (or designated time), a data voltage Vdata, which corresponds to an image signal voltage or a voltage corresponding to the data voltage Vdata.

The drain node or the source node of the switching transistor Ts may be electrically connected to the corresponding data line DL, and the source node or the drain node of the switching transistor Ts may be electrically connected to the first node N1 of the driving transistor Td. In addition, the gate node of the switching transistor Ts may be electrically connected to the corresponding gate line and receive a scan signal SCAN.

The on/off operation of the switching transistor Ts may be controlled as the scan signal SCAN is applied to the gate node through the corresponding gate line.

The switching transistor Ts may be turned on by the scan signal SCAN and transmit the data voltage Vdata, which is supplied from the corresponding data line DL, to the first node N1 of the driving transistor Td.

Meanwhile, the storage capacitor Cst may be an external capacitor intentionally designed outside the driving transistor Td instead of a parasitic capacitor that is an internal capacitor present between the first node N1 and the second node N2 of the driving transistor Td.

For example, the driving transistor Td and the switching transistor Ts may each be an n-type transistor or a p-type transistor.

The structure of each of the subpixels illustrated in FIG. 3 is a 2T (transistor) IC (capacitor) structure that is just an illustrative example. The subpixel may further include one or more transistors. In some instances, the subpixel may further include one or more capacitors. In addition, the plurality of subpixels may each have the identical structure. Some of the plurality of subpixels may have different structures.

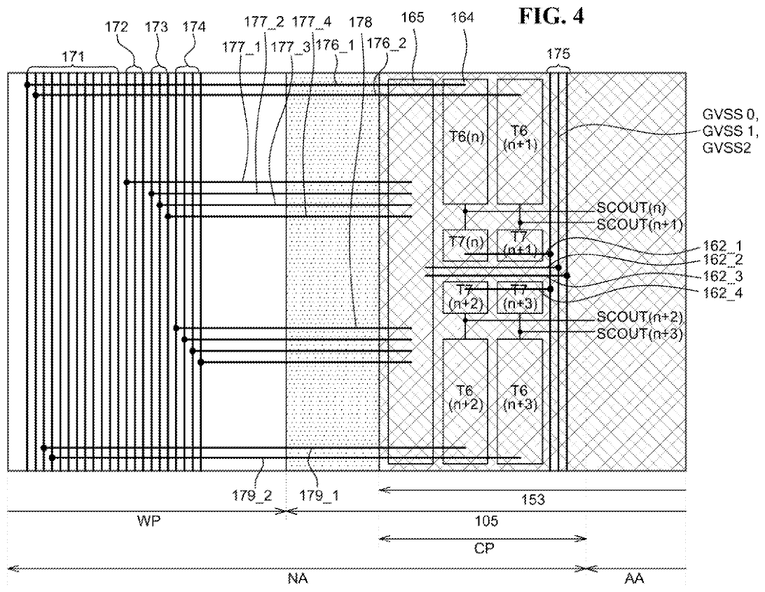

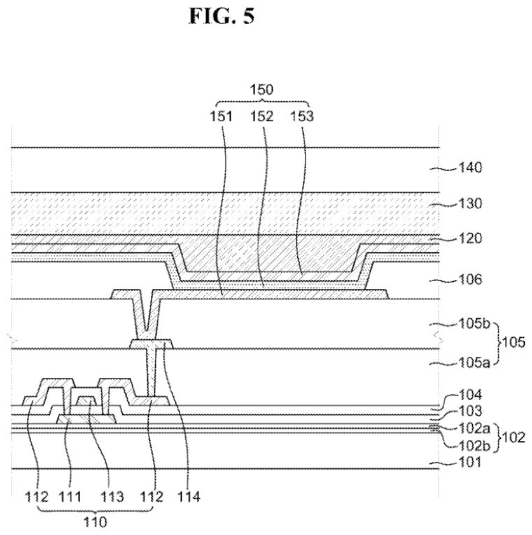

Hereinafter, a structure of a pixel of the display device according to a first exemplary aspect of the present disclosure will be described in more detail with reference to FIGS. 4 and 5.

FIG. 4 is a plan view illustrating a part of a display panel according to a first exemplary aspect of the present disclosure.

FIG. 4 is an enlarged view of part A in FIG. 2 and illustrates a part of the non-display area in which a GIP type gate drive circuit is disposed.

With reference to FIG. 4, the display panel according to the first exemplary aspect of the present disclosure may include the display area AA in which images are displayed, and the non-display area NA in which no image is displayed.

In the display panel, the plurality of subpixels for displaying images may be disposed in the display area AA. In the non-display area NA, the drive circuits may be electrically connected or the drive circuits may be mounted. The pad part connected to the integrated circuit, the printed circuit board, or the like may be disposed in the non-display area NA.

The data drive circuit may be a circuit for operating the plurality of data lines and supply the data signals to the plurality of data lines. The gate drive circuit may be a circuit for operating the plurality of gate lines and supply the gate signals to the plurality of gate lines.

The gate drive circuit may output a gate signal with a turn-on-level voltage or output a gate signal with a turn-off-level voltage under the control of the timing controller. The gate drive circuit may sequentially operate the plurality of gate lines by sequentially supplying the gate signals with the turn-on-level voltages to the plurality of gate lines.

The gate drive circuit may be connected to the display panel in a tape-automated bonding (TAB) manner, connected to the bonding pad of the display panel in a chip-on-glass (COG) or chip-on-panel (COP) manner, or connected to the display panel in a chip-on-film (COF) manner. Alternatively, the gate drive circuit may be formed as a gate-in-panel (GIP) type in the non-display area NA of the display panel. The gate drive circuit may be disposed on an upper portion of the substrate or connected to the substrate. For example, in case that the gate drive circuit is the GIP type, the gate drive circuit may be disposed in the non-display area NA of the substrate. In case that the gate drive circuit is a chip-on-glass (COG) type, a chip-on-film (COF) type, or the like, the gate drive circuit may be connected to the substrate.

The gate drive circuit may be connected to one side (e.g., a left or right side) of the display panel. Depending on operating methods, panel designing methods, or the like, the gate drive circuits may be connected to two opposite sides (e.g., left and right sides) of the display panel or connected to two or more side surfaces among the four side surfaces of the display panel.

In the case of the present disclosure, a wiring part WP and a circuit part CP of the gate drive circuit may be separated and disposed in the non-display area NA.

For example, the wiring part WP may be disposed outside the non-display area NA, and the circuit part CP may be disposed inside the non-display area NA.

For example, a plurality of clock lines 171 and 172, a plurality of signal lines 173, and a plurality of high-potential power voltage lines 174 may be disposed at the wiring part WP. However, the present disclosure is not limited thereto.

For example, the plurality of clock lines 171 and 172 may include a scan clock signal line 171 configured to transmit a scan clock signal SCCLK, and a carry clock signal line 172 configured to transmit a carry clock signal CRCLK.

FIG. 4 illustrates an example in which twelve scan clock signal lines 171 are disposed. However, the present disclosure is not limited thereto.

In addition, FIG. 4 illustrates an example in which three carry clock signal lines 172 are disposed. However, the present disclosure is not limited thereto.

The gate drive circuit may generate scan pulses SCOUT (n), SCOUT (n+1), SCOUT (n+2), and SCOUT (n+3) by using the scan clock signal SCCLK and supply the generated scan pulses SCOUT (n), SCOUT (n+1), SCOUT (n+2), and SCOUT (n+3) to the corresponding gate line disposed on display panel. Therefore, the subpixel connected to the corresponding gate line may receive the scan pulse SCOUT (n), SCOUT (n+1), SCOUT (n+2), and SCOUT (n+3).

For example, the SCOUT (n) may be a GIP output of an (n)th line, and the corresponding GIP output may be used as a scan signal in the subpixel.

For example, the plurality of signal lines 173 may include a gate start signal line configured to transmit a gate start signal VST, a gate reset signal line configured to transmit a gate reset signal RST, and a pixel line selection/deselection signal line configured to transmit a pixel line selection/deselection signal LSP. However, the present disclosure is not limited thereto.

The gate reset signal RST may be a signal for discharging a Q node voltage after real-time (RT) compensation. In addition, the gate reset signal RST may be a signal for resetting a circuit after a one-frame operation of the GIP circuit.

The RT compensation is performed by randomly selecting one gate line. The pixel line selection/deselection signal LSP may be a signal for selecting any gate line.

The plurality of high-potential power voltage lines 174 may transmit a high-potential power voltage GVDD.

FIG. 4 illustrates an example in which four high-potential power voltage lines 174 are disposed. However, the present disclosure is not limited thereto.

FIG. 4 illustrates an example in which the plurality of clock lines 171 and 172, the plurality of signal lines 173, and the plurality of high-potential power voltage lines 174 are sequentially disposed at the wiring part WP. However, the present disclosure is not limited thereto.

The wiring part WP and the circuit part CP may be spaced apart from each other at a predetermined interval.

A logic circuit part 165, a plurality of transistor parts 164, and a low-potential power voltage line 175 may be disposed on the circuit part CP. However, the present disclosure is not limited thereto.

For example, the logic circuit part 165 may be connected between the shift register and the level shifter and control the output of the gate line.

The level shifter may convert an output logic level of the shift register into an on/off voltage of the gate line.

The electric current buffer may amplify the electric current in consideration of a load of the gate line.

For example, the logic circuit part 165 may include an inverter configured to inversely output the GOE (in FIG. 1) signal supplied from the timing controller, and a logical sum gate configured to perform a logical operation on a signal outputted through the inverter and a signal outputted through the shift register and output a control logic level. However, the present disclosure is not limited thereto.

The level shifter may select any one of a gate high voltage, a first gate low voltage, and a second gate low voltage and convert the logic level, which is outputted through the logic circuit part 165, into the on/off voltage of the gate line.

For example, the transistor part 164 may include a plurality of transistors T6 (n), T6 (n+1), T6 (n+2), T6 (n+3), T7 (n), T7 (n+1), T7 (n+2), and T7 (n+3).

For example, a (n)th sixth transistor T6 (n) may be connected to an (n)th seventh transistor T7 (n). However, the present disclosure is not limited thereto.

An (n+1)th sixth transistor T6 (n+1) may be connected to an (n+1)th seventh transistor T7 (n+1). However, the present disclosure is not limited thereto.

An (n+2)th sixth transistor T6 (n+2) may be connected to an (n+2)th seventh transistor T7 (n+2). However, the present disclosure is not limited thereto.

An (n+3)th sixth transistor T6 (n+3) may be connected to an (n+3)th seventh transistor T7 (n+3). However, the present disclosure is not limited thereto.

The plurality of transistors T6 (n), T6 (n+1), T6 (n+2), T6 (n+3), T7 (n), T7 (n+1), T7 (n+2), and T7 (n+3) may be connected to the plurality of scan clock signal lines 171 through first to fourth connection lines 176_1, 176_2, 179_1, and 179_2.

For example, the (n)th sixth transistor T6 (n) may be connected to the first scan clock signal line 171 through the first connection line 176_1.

For example, the (n+1)th sixth transistor T6 (n+1) may be connected to the second scan clock signal line 171 through the second connection line 176_2.

For example, the (n+2)th sixth transistor T6 (n+2) may be connected to the third scan clock signal line 171 through the third connection line 179_1.

For example, the (n+3)th sixth transistor T6 (n+3) may be connected to the fourth scan clock signal line 171 through the fourth connection line 179_2.

In addition, for example, the logic circuit part 165 may be connected to the carry clock signal line 172 through the fifth connection line 177_1.

For example, the logic circuit part 165 may be connected to the first signal line 173 through a sixth connection line 177_2. The first signal line 173 may be a gate start signal line configured to transmit the gate start signal VST. However, the present disclosure is not limited thereto.

For example, the logic circuit part 165 may be connected to the second signal line 173 through a seventh connection line 177_3. The second signal line 173 may be a gate reset signal line configured to transmit the gate reset signal RST. However, the present disclosure is not limited thereto.

For example, the logic circuit part 165 may be connected to the third signal line 173 through an eighth connection line 177_4. Further, the third signal line 173 may be a pixel line selection/deselection signal line configured to transmit the pixel line selection/deselection signal LSP. However, the present disclosure is not limited thereto.

In addition, for example, the logic circuit part 165 may be connected to the plurality of high-potential power voltage lines 174 through a plurality of ninth connection lines 178.

The plurality of low-potential power voltage lines 175 may respectively transmit a plurality of low-potential power voltages GVSS0, GVSS1, and GVSS2.

GVSS0 may be a voltage for setting a low voltage of the GIP output (scan pulse SCOUT).

GVSS1 may be a voltage for setting a low voltage in the inverter in the GIP.

GVSS2 may be a voltage for setting a Q node and a QB node in the GIP to a low voltage.

For example, the (n)th seventh transistor T7 (n) may be connected to the first low-potential power voltage line 175 through a tenth connection line 162_1. However, the present disclosure is not limited thereto.

In addition, the logic circuit part 165 may be connected to the second low-potential power voltage line 175 through an eleventh connection line 162_2. However, the present disclosure is not limited thereto.

In addition, the logic circuit part 165 may be connected to the third low-potential power voltage line 175 through a twelfth connection line 162_3. However, the present disclosure is not limited thereto.

In addition, the (n+2)th seventh transistor T7 (n+2) may be connected to the first low-potential power voltage line 175 through a thirteenth connection line 162_4. However, the present disclosure is not limited thereto.

FIG. 4 illustrates an example in which the logic circuit part 165, the plurality of transistors parts 164, and the low-potential power voltage line 175 are sequentially disposed on the circuit part CP. However, the present disclosure is not limited thereto.

As described above, in the present disclosure, the wiring part WP and the circuit part CP of the gate drive circuit may be separated and disposed in the non-display area NA.

In a top-emission type display device, a dam for suppressing moisture penetration is disposed between a first substrate at a lower side and a second substrate at an upper side in the bezel area to ensure moisture transmission reliability. In addition, a light-emitting element, a plurality of organic films, and a plurality of inorganic films are deposited on an upper portion of the first substrate, and the organic and inorganic films each have a process dispersion with respect to a deposition area. In addition, the GIP circuit applied to operate the display device is designed in the gate bezel, and the GIP design area is designed in consideration of process dispersion areas of dam areas and organic and inorganic films to optimize the GIP performance and ensure the reliability.

If a dispersion defect occurs during a process of depositing the cathode, a line dim caused by charging deviation along a vertical line is formed by the fluctuation in parasitic capacity between the cathode and the line of the gate drive circuit. For this reason, image quality implemented by the display device may deteriorate. In addition, A screen abnormality of the display panel may occur because of a horizontal dim and a GIP operation defect even in a case in which a short circuit occurs between the line and the cathode.

In addition, in case that the dam and the planarization layer overlap each other, a crack may be formed in an insulation layer on an upper portion of the light-emitting element because the dam is pushed in the overlapping area. For this reason, a GIP operation defect may occur because the GIP transistor becomes a conductor because of hydrogen penetration. In addition, in an area in which no planarization layer is present, the parasitic capacity may increase because of the cathode, and particularly, a horizontal dim defect may occur on a line of the gate drive circuit in case that the parasitic capacity fluctuates because of a tolerance of the cathode.

Therefore, according to the present disclosure, the wiring part WP and the circuit part CP of the gate drive circuit may be separated and disposed in the non-display area NA.

In addition, according to the present disclosure, the wiring part WP may be disposed outside the non-display area NA, and the circuit part CP may be disposed inside the non-display area NA. The wiring part WP and the circuit part CP may be spaced apart from each other at a predetermined interval. In addition, a cathode 153 may be disposed inside the non-display area NA so as not to overlap the wiring part WP. That is, for example, the cathode 153 may be disposed inside the non-display area NA to cover only the circuit part CP.

In addition, according to the present disclosure, a planarization layer 105 may be disposed to be spaced apart from the dam. That is, for example, the planarization layer 105 may extend to the non-display area NA to cover the circuit part CP and be disposed to be spaced apart from the wiring part WP.

Therefore, the line of the wiring part WP, for example, a short circuit may be suppressed between the plurality of clock lines 171 and 172, the plurality of signal lines 173, the plurality of high-potential power voltage lines 174, and the cathode 153.

In addition, it is possible to suppress a screen abnormality defect of the display panel such as an operation defect and a horizontal dim of the gate drive circuit.

FIG. 5 is a cross-sectional view of a subpixel of the display panel in FIG. 4.

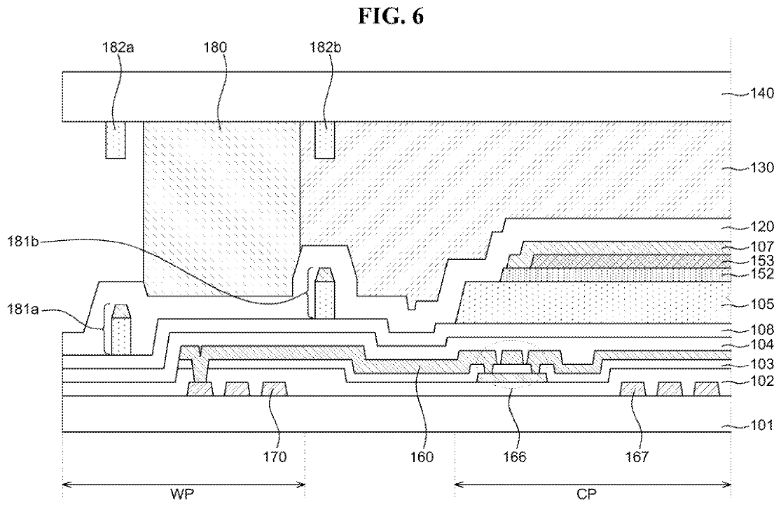

FIG. 6 is a view illustrating a part of a cross-sectional structure of the display panel in FIG. 4.

FIG. 6 illustrates a cross-sectional structure of a part of the non-display area including the wiring part WP and the circuit part CP.

With reference to FIGS. 5 and 6, in the display device according to the first exemplary aspect of the present disclosure, a driving element 110 may be disposed on an upper portion of a first substrate 101.

Further, the planarization layer 105 may be disposed on the upper portion of the driving element 110.

The light-emitting element 150, which is electrically connected to the driving element 110, may be disposed on an upper portion of the planarization layer 105, and an insulation layer 120 may be disposed on an upper portion of the light-emitting element 150, thereby suppressing the penetration of oxygen and moisture into the light-emitting element 150.

A bonding film 130 and a second substrate (sealing substrate) 140 may be sequentially disposed on the insulation layer 120.

However, the display device according to the first exemplary aspect of the present disclosure is not limited to the above-mentioned layered structure.

The first substrate 101 may be a glass or plastic substrate. In case that the substrate is a plastic substrate, a polyimide-based material or a polycarbonate-based material is used, such that the substrate may have flexibility. In particular, polyimide is widely used for the plastic substrate because polyimide is a material that may be applied to a high-temperature process and used for coating.

For example, a GIP signal/power line 170 may be disposed on the first substrate 101 of the wiring part WP. The GIP signal/power line 170 may be referred to as a line of the wiring part WP.

As described above, the GIP signal/power line 170 may include a plurality of clock lines, a plurality of signal lines, and a plurality of high-potential power voltage lines.

In addition, for example, a conductive layer 167 may be disposed on the first substrate 101 of the circuit part CP. The conductive layer 167 may be a low-potential power voltage line.

A buffer layer 102 may be disposed on an upper portion of the first substrate 101 including the GIP signal/power line 170 and the conductive layer 167.

The buffer layer 102 is a layer for protecting various types of electrodes and lines from impurities such as alkaline ions leaking from the first substrate 101 or lower layers. The buffer layer 102 may have a multilayer structure including a first buffer layer 102a and a second buffer layer 102b. However, the present disclosure is not limited thereto. The buffer layer 102 may be made of silicon oxide (SiOx) or silicon nitride (SiNx) or configured as a multilayer including silicon oxide (SiOx) or silicon nitride (SiNx).

The buffer layer 102 may delay the diffusion of moisture and/or oxygen penetrating into the first substrate 101. In addition, the buffer layer 102 may include a multi-buffer and/or an active buffer. The active buffer may serve to protect an active layer 111 of the driving element 110, and the active layer 111 is made of a semiconductor. The active buffer may serve to block various types of defects introduced from the first substrate 101. The active buffer may be made of amorphous silicon (a-Si) or the like.

The buffer layer 102 may extend to the non-display area. For example, the buffer layer 102 may extend to cover the GIP signal/power line 170. However, the present disclosure is not limited thereto.

The driving element 110 may be configured such that the active layer 111, a gate insulation layer 103, a gate electrode 113, an interlayer insulation layer 104, a source electrode, and a drain electrode 112 are sequentially disposed. The driving element 110 may be electrically connected to the light-emitting element 150 through a connection electrode 114 which may transmit an electric current or signal to the light-emitting element 150.

The active layer 111 may be positioned on the buffer layer 102. The active layer 111 may be made of polysilicon (p-Si). In this case, a predetermined area of the active layer 111 may be doped with impurities. In addition, the active layer 111 may be made of amorphous silicon (a-Si) or an organic semiconductor material such as pentacene. In addition, the active layer 111 may be made of an oxide semiconductor.

For example, a GIP transistor 166 may be disposed on the buffer layer 102 of the circuit part CP.

For example, the gate insulation layer 103 may be positioned on the active layer 111. The gate insulation layer 103 may be made of an insulating inorganic material such as silicon oxide (SiOx) and silicon nitride (SiNx). In addition, the gate insulation layer 103 may be made of an insulating organic material or the like.

The gate insulation layer 103 may extend to the non-display area. For example, the gate insulation layer 103 may extend to cover the GIP signal/power line 170. However, the present disclosure is not limited thereto.

In addition, the gate electrode 113 may be positioned on the gate insulation layer 103. The gate electrode 113 may be made of various electrically conductive materials, for example, magnesium (Mg), aluminum (Al), nickel (Ni), chromium (Cr), molybdenum (Mo), tungsten (W), gold (Au), or an alloy thereof.

For example, various types of connection lines 160 may be disposed at the wiring part WP and the gate insulation layer 103 of the circuit part CP.

The connection line 160 may be a jumping line that connects the GIP signal/power line 170 of the wiring part WP to the GIP circuit (or transistor) of the circuit part CP.

The connection line 160 may electrically connect the wiring part WP and the circuit part CP.

For example, the interlayer insulation layer 104 may be positioned on the gate electrode 113. The interlayer insulation layer 104 may be made of an insulating material such as silicon oxide (SiOx) and silicon nitride (SiNx). In addition, the interlayer insulation layer 104 may be made of an insulating organic material or the like.

For example, the interlayer insulation layer 104 may extend to the non-display area. For example, the interlayer insulation layer 104 may extend to cover the wiring part WP.

A contact hole, through which source and drain areas are exposed, may be formed by selectively removing the gate insulation layer 103 and the interlayer insulation layer 104. The source electrode and the drain electrode 112 may each have a single-layer or multilayer structure disposed on the interlayer insulation layer 104 and made of a material for an electrode. As necessary, a protective layer (passivation layer) 108 made of an inorganic insulating material may be formed to cover the source electrode and the drain electrode 112.

For example, the protective layer 108 may extend to the non-display area. For example, the protective layer 108 may extend to cover the wiring part WP.

The planarization layer 105 may be disposed on the upper portion of the driving element 110 configured as described above.

The planarization layer 105 may have a multilayer structure including at least two layers. For example, the planarization layer 105 may include a first planarization layer 105a and a second planarization layer 105b. The first planarization layer 105a may be disposed to cover the driving element 110 and disposed such that the source electrode and the drain electrode 112 of the driving element 110 are partially exposed.

The planarization layer 105 may extend to the non-display area. For example, the planarization layer 105 may extend to cover the circuit part CP. In addition, for example, the planarization layer 105 may be spaced apart from the wiring part WP and may not overlap the wiring part WP.

In addition, for example, the planarization layer 105 may be disposed to be spaced apart from a dam 180. That is, for example, the planarization layer 105 may extend to the non-display area to cover the circuit part CP and be disposed to be spaced apart from the wiring part WP.

In addition, for example, the circuit part CP may be disposed to correspond to the end of the planarization layer 105, which may reduce the parasitic capacity between the cathode 153 and the GIP signal/power line 170.

The planarization layer 105 may be an overcoat layer. However, the present disclosure is not limited thereto.

The connection electrode 114 may be disposed on the first planarization layer 105a and electrically connect the driving element 110 and the light-emitting element 150. In addition, although not illustrated in FIG. 5, various metal layers may be disposed on the first planarization layer 105a and serve as electrodes and electric wires such as data lines or signal lines.

In addition, the second planarization layer 105b may be disposed on an upper portion of the first planarization layer 105a and an upper portion of the connection electrode 114. The configuration in which the planarization layer 105 of the first exemplary aspect of the present disclosure is provided as two layers is based on the fact that the number of various types of signal lines increases as the display device has high resolution. The additional layer is provided because it is difficult to dispose all the lines on a single layer while ensuring minimum intervals. The addition of the additional layer (i.e., the second planarization layer 105b) may provide a margin for disposing lines, which further facilitates the disposition design of lines/electrodes.

In addition, in case that a dielectric material is used for the planarization layer 105 having a multilayer structure, the planarization layer 105 may serve to create capacitance between metal layers.

The second planarization layer 105b may be formed such that a part of the connection electrode 114 is exposed. The drain electrode 112 of the driving element 110 and an anode 151 of the light-emitting element 150 may be electrically connected by the connection electrode 114.

Meanwhile, the light-emitting element 150 may be configured by sequentially disposing the anode 151, a plurality of organic layers 152, and the cathode 153. For example, the light-emitting element 150 may include the anode 151 formed on the planarization layer 105, the organic layer 152 formed on the anode 151, and the cathode 153 formed on the organic layer 152.

The display device may be implemented as a top emission type or a bottom emission type. In the case of the top emission type, a reflective layer made of an opaque conductive material with high reflectance, for example, silver (Ag), gold (Au), aluminum (Al), molybdenum (Mo), tungsten (W), chromium (Cr), or an alloy thereof may be additionally disposed on a lower portion of the anode 151 so that light, which is emitted from the organic layer 152, is reflected by the anode 151 and propagates upward, for example, in a direction toward the cathode 153 at the upper side. In contrast, in the case of the bottom emission type, the anode 151 may be made of only a transparent electrically conductive material such as indium tin oxide (ITO), indium zinc oxide (IZO), or indium gallium zinc oxide (IGZO). Hereinafter, the description will be made on the assumption that the display device of the present disclosure is the top emission type. However, the present disclosure is not limited thereto.

A bank 106 may be provided on the planarization layer 105 and formed in the remaining area excluding the light-emitting area. That is, the bank 106 has a bank hole through which the anode 151 corresponding to the light-emitting area is exposed. The bank 106 may be made of an inorganic insulating material such as silicon nitride (SiNx) and silicon oxide (SiOx) or made of an organic insulating material such as BCB, acrylic resin and imide-based resin.

The bank 106 may extend to the non-display area.

The organic layer 152 may be disposed on the anode 151 exposed by the bank 106. The organic layer 152 may include a light-emitting layer, an electron injection layer, an electron transport layer, a hole transport layer, a hole injection layer, and the like.

The organic layer 152 may extend to the non-display area.

For example, in the circuit part CP, the organic layer 152 may be disposed on the planarization layer 105.

The cathode 153 may be disposed on the organic layer 152.

In the case of the top emission type, the cathode 153 may include a transparent electrically conductive material. The cathode 153 may be made of indium tin oxide (ITO), indium zinc oxide (IZO), indium gallium zinc oxide (IGZO), or the like. In the case of the bottom emission type, the cathode 153 may include one of metallic materials such as gold (Au), silver (Ag), aluminum (Al), molybdenum (Mo), magnesium (Mg), palladium (Pd), and copper (Cu) or an alloy thereof. Alternatively, the cathode 153 may be configured by stacking a layer made of a transparent electrically conductive material such as indium tin oxide (ITO), indium zinc oxide (IZO), and indium gallium zinc oxide (IGZO) and a layer made of metallic materials such as gold (Au), silver (Ag), aluminum (Al), molybdenum (Mo), magnesium (Mg), palladium (Pd), and copper (Cu) or an alloy thereof. However, the present disclosure is not limited thereto.

The cathode 153 may extend to the non-display area.

For example, in the circuit part CP, the cathode 153 may be disposed on the organic layer 152. In addition, for example, the cathode 153 may be disposed to cover the organic layer 152.

In addition, the cathode 153 may be disposed inside the non-display area so as not to overlap the wiring part WP. That is, for example, the cathode 153 may be disposed inside the non-display area to cover only the circuit part CP. Therefore, it is possible to suppress the fluctuation in line load of the GIP signal/power line 170 caused by the parasitic capacity between the cathode 153 and the GIP signal/power line 170. Because the cathode 153 and the wiring part WP do not overlap each other as described above, the line load of the GIP signal/power line 170 does not fluctuate even though the cathode 153 has a tolerance.

For example, the organic layer 152 and the cathode 153 may be disposed to be spaced apart from the end of the planarization layer 105 at a predetermined distance. However, the present disclosure is not limited thereto.

A capping layer 107 may be disposed on the upper portion of the light-emitting element 150. The capping layer 107 may be made of a material with a large refractive index and a high optical absorption rate to reduce irregular reflection of external light.

The capping layer 107 may extend to the non-display area.

For example, in the circuit part CP, the capping layer 107 may be disposed on the cathode 153. In addition, for example, the capping layer 107 may be disposed to cover the cathode 153.

For example, the capping layer 107 may be disposed to be spaced apart from the end of the planarization layer 105 at a predetermined distance. However, the present disclosure is not limited thereto.

A plurality of lower dams 181a and 181b may be disposed on the upper portion of the wiring part WP in the non-display area.

For example, the lower dams 181a and 181b may include a lower outer dam 181a and a lower inner dam 181b. However, the present disclosure is not limited thereto.

For example, the lower dams 181a and 181b may include the planarization layer 105 and the capping layer 107. However, the present disclosure is not limited thereto. For example, the lower dams 181a and 181b may include the planarization layer 105 and the bank 106.

The lower inner dam 181b may be disposed on the protective layer 108 and disposed at one side of the dam 180, i.e., disposed inside the dam 180. The lower inner dam 181b may inhibit the dam 180 from being spread into the display device. In this case, a fine concave-convex pattern may be formed on an upper portion of the lower inner dam 181b to inhibit the dam 180 from easily overflowing. For example, the lower inner dam 181b may be configured as an organic film made of a material such as polyimide-based resin, acrylic resin, or benzocyclobutene (BCB) that may form the fine pattern.

The insulation layer 120 may be disposed on the capping layer 107.

The insulation layer 120 may be an inorganic layer, for example, configured as a multilayer including silicon oxide (SiOx) or silicon nitride (SiNx).

The insulation layer 120 may extend to the non-display area.

The insulation layer 120 may be disposed to cover the cathode 153 and the planarization layer 105.

The insulation layer 120 may extend to the wiring part WP to cover the lower dams 181a and 181b.

The bonding film 130 and the second substrate 140 may be disposed on the insulation layer 120.

The bonding film 130, together with the insulation layer 120 and the second substrate 140, may protect the light-emitting element 150 in the display area and the circuit part CP in the non-display area from outside moisture, oxygen, impact, and the like. The bonding film 130 may further include a moisture absorbent. The moisture absorbent may include particles having hygroscopicity. The moisture absorbent may absorb moisture, oxygen, and the like from the outside, thereby minimizing a degree to which moisture and oxygen penetrate into the light-emitting element 150 and the circuit part CP. However, the present specification is not limited thereto.

The bonding film 130 may include a filler.

The filler may be made of a transparent material so that brightness does not deteriorate while light emitted from the light-emitting element 150 passes through the second substrate 140. For example, the filler may be made of epoxy or olefin and include talc, calcium oxide (CaO), barium oxide (BaO), zeolite (zeolite), silicon oxide (SiO), and the like.

The second substrate 140 may be disposed on the bonding film 130.

The second substrate 140, together with the bonding film 130, may protect the light-emitting element 150. The second substrate 140 may protect the light-emitting element 150 from outside moisture, oxygen, impact, and the like.

A plurality of upper dams 182a and 182b may be disposed on the upper portion of the second substrate 140 of the wiring part WP.

For example, the upper dams 182a and 182b may include an upper outer dam 182a and an upper inner dam 182b. However, the present disclosure is not limited thereto.

For example, the upper outer dam 182a and the upper inner dam 182b may be respectively formed to correspond to the lower outer dam 181a and the lower inner dam 181b. However, the present disclosure is not limited thereto.

In addition, the dam 180 may be provided at the edge of the first substrate 101 and disposed between the first substrate 101 and the second substrate 140. The dam 180 may reinforce a bonding force between the first substrate 101 and the second substrate 140 and block moisture.

The dam 180 may be disposed at the wiring part WP in the non-display area. For example, the dam 180 may be disposed on a plane to surround the circuit part CP and the bonding film 130. The dam 180, together with the bonding film 130, may join and seal the first substrate 101 and the second substrate 140. Therefore, the dam 180 may be disposed in an area in which the first substrate 101 and the second substrate 140 overlap each other.

The dam 180 may be disposed to be spaced apart from the planarization layer 105 and the circuit part CP at a predetermined distance. Therefore, the dam 180 and the planarization layer 105 do not overlap each other, which may suppress cracks in the insulation layer 120 that may be formed when the dam 180 and the planarization layer 105 are pushed.

The GIP signal/power line 170 may be disposed on a lower portion of the dam 180. Further, because the lower inner dam 181b is disposed inside the dam 180, the lower inner dam 181b may be disposed to be spaced apart from the GIP signal/power line 170 at a predetermined distance. Therefore, it is possible to suppress the overlap the wiring part WP even though a tolerance occurs when the cathode 153 is formed. This configuration will be described below in detail with reference to the following drawings.

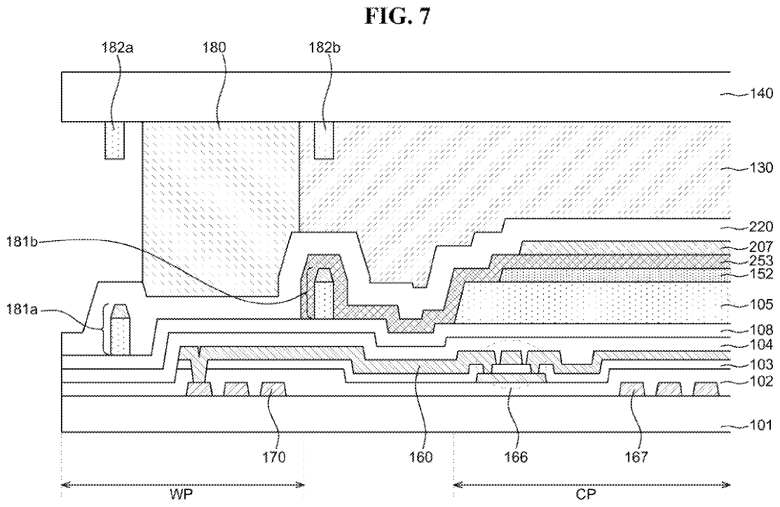

FIG. 7 is a view illustrating a part of a cross-sectional structure of a display panel according to a second exemplary aspect of the present disclosure.

The display panel according to the second exemplary aspect of the present disclosure in FIG. 7 is substantially identical in configuration to the display device according to the exemplary aspect of the present disclosure in FIG. 6, except for a cathode 253. Therefore, repeated descriptions of the identical components will be omitted.

FIG. 7 illustrates a cross-sectional structure of a part of the non-display area including the wiring part WP and the circuit part CP.

With reference to FIG. 7, for example, the GIP signal/power line 170 may be disposed on the first substrate 101 of the wiring part WP.

In addition, for example, the conductive layer 167 may be disposed on the first substrate 101 of the circuit part CP. The conductive layer 167 may be a low-potential power voltage line.

The buffer layer 102 may be disposed on the upper portion of the first substrate 101 on which the GIP signal/power line 170 and the conductive layer 167 are disposed.

For example, the GIP transistor 166 may be disposed on the buffer layer 102 of the circuit part CP.

The gate insulation layer 103 may be disposed on the upper portion of the first substrate 101 on which the GIP transistor 166 is disposed.

For example, various types of connection lines 160 may be disposed at the wiring part WP and the gate insulation layer 103 of the circuit part CP.

The connection line 160 may electrically connect the wiring part WP and the circuit part CP.

The interlayer insulation layer 104, the protective layer 108, and the planarization layer 105 may be disposed on the upper portion of the first substrate 101 on which the connection line 160 is disposed.

The organic layer 152 and cathode 253 may be disposed on the upper portion of the planarization layer 105.

According to the second exemplary aspect of the present disclosure, the cathode 253 may be formed to the lower inner dam 181b over the circuit part CP by a tolerance. However, the GIP signal/power line 170 may be disposed on the lower portion of the dam 180, and the lower inner dam 181b is disposed to be spaced apart from the GIP signal/power line 170 at a predetermined distance, thereby suppressing the overlap between the cathode 253 and the wiring part WP.

A capping layer 207 may be disposed on the cathode 253.

An insulation layer 220 may be disposed on the capping layer 207. For example, the insulation layer 220 may extend to the non-display area.

The insulation layer 220 may be disposed to cover the cathode 253 and the planarization layer 105.

The insulation layer 220 may extend to the wiring part WP to cover the lower dams 181a and 181b. For example, the insulation layer 220 may cover the cathode 253 formed to the lower inner dam 181b, such that the insulation layer 220 may be in contact with a top surface of the cathode 253.

Meanwhile, because the wiring part WP and the circuit part CP are separated and disposed, the plurality of connection lines 160 for connecting the wiring part WP and the circuit part CP may be required, and a line dim may be formed by a difference in resistance between the plurality of connection lines 160.

Therefore, the present disclosure may provide a compensation pattern for compensating for a resistance deviation caused by a difference in length between the adjacent connection lines 160. The compensation pattern will be described in detail with reference to the drawings.

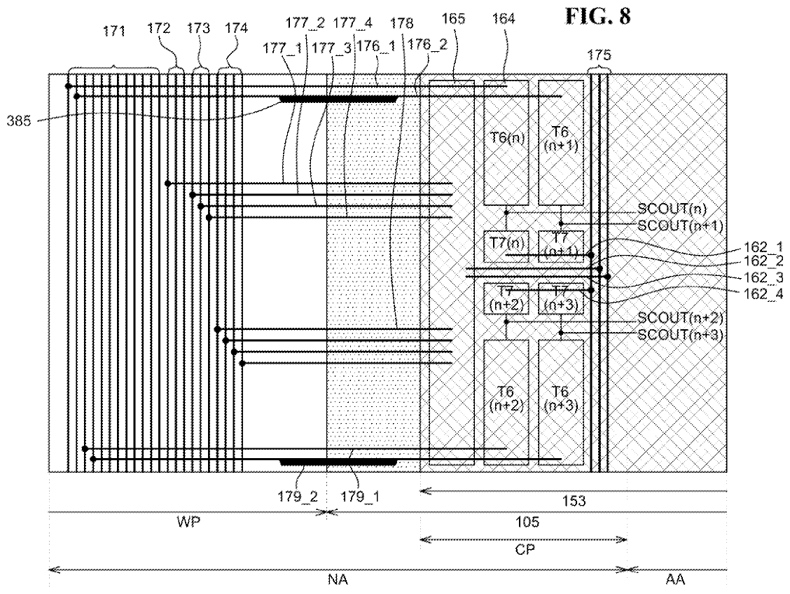

FIG. 8 is a plan view illustrating a part of a display panel according to a third exemplary aspect of the present disclosure.

The display panel according to the third exemplary aspect of the present disclosure in FIG. 8 is substantially identical in configuration to the display device according to the exemplary aspect of the present disclosure in FIG. 4, except for a configuration of a connection line. Therefore, repeated descriptions of the identical components will be omitted.

FIG. 8 illustrates a part of the non-display area in which the GIP type gate drive circuit is disposed.

With reference to FIG. 8, the display panel according to the second exemplary aspect of the present disclosure may include the display area AA in which images are displayed, and the non-display area NA in which no image is displayed.

According to the present disclosure, the wiring part WP and the circuit part CP of the gate drive circuit may be separated and disposed in the non-display area NA.

For example, the wiring part WP may be disposed outside the non-display area NA, and the circuit part CP may be disposed inside the non-display area NA. The wiring part WP and the circuit part CP may be spaced apart from each other at a predetermined interval.

For example, the plurality of clock lines 171 and 172, the plurality of signal lines 173, and the plurality of high-potential power voltage lines 174 may be disposed at the wiring part WP. However, the present disclosure is not limited thereto.

For example, the plurality of clock lines 171 and 172 may include the scan clock signal line 171 configured to transmit the scan clock signal SCCLK, and the carry clock signal line 172 configured to transmit the carry clock signal CRCLK.

The scan clock signal SCCLK may be a signal for synchronizing output timings so that the GIP output may occur at a necessary timing.

The carry clock signal CRCLK may be a signal required to perform a sequential operation of the GIP. The sequential operation of the GIP may be implemented in response to the carry clock signal CRCLK, the signal before the GIP, and the signal after the GIP.

For example, the plurality of signal lines 173 may include the gate start signal line configured to transmit the gate start signal VST, the gate reset signal line configured to transmit the gate reset signal RST, and the pixel line selection/deselection signal line configured to transmit the pixel line selection/deselection signal LSP. However, the present disclosure is not limited thereto.

The logic circuit part 165, the plurality of transistor parts 164, and the low-potential power voltage line 175 may be disposed on the circuit part CP. However, the present disclosure is not limited thereto.

For example, the transistor part 164 may include the plurality of transistors T6 (n), T6 (n+1), T6 (n+2), T6 (n+3), T7 (n), T7 (n+1), T7 (n+2), and T7 (n+3).

T6 (n) may be a pull-up buffer that outputs the high-level gate voltage VGH from the (n)th line.

T6 (n+1) may be a pull-up buffer that outputs the high-level gate voltage VGH from the (n+1)th line.

T6 (n+2) may be a pull-up buffer that outputs the high-level gate voltage VGH from the (n+2)th line.

T6 (n+3) may be a pull-up buffer that outputs the high-level gate voltage VGH from the (n+3)th line.

T7 (n) may be a pull-down buffer that outputs the low-level gate voltage VGL from the (n)th line.

T7 (n+1) may be a pull-down buffer that outputs the low-level gate voltage VGL from the (n+1)th line.

T7 (n+2) may be a pull-down buffer that outputs the low-level gate voltage VGL from the (n+2)th line.

T7 (n+3) may be a pull-down buffer that outputs the low-level gate voltage VGL from the (n+3)th line.

The plurality of transistors T6 (n), T6 (n+1), T6 (n+2), T6 (n+3), T7 (n), T7 (n+1), T7 (n+2), and T7 (n+3) may be connected to the plurality of scan clock signal lines 171 through the first to fourth connection lines 176_1, 176_2, 179_1, and 179_2.

For example, the (n)th sixth transistor T6 (n) may be connected to the first scan clock signal line 171 through the first connection line 176_1.

For example, the (n+1)th sixth transistor T6 (n+1) may be connected to the second scan clock signal line 171 through the second connection line 176_2.

For example, the (n+2)th sixth transistor T6 (n+2) may be connected to the third scan clock signal line 171 through the third connection line 179_1.

For example, the (n+3)th sixth transistor T6 (n+3) may be connected to the fourth scan clock signal line 171 through the fourth connection line 179_2.

In this case, there occurs a resistance deviation caused by a difference in length between the first connection line 176_1 and the second connection line 176_2. That is, the second connection line 176_2, which connects the (n+1)th sixth transistor T6 (n+1) and the second scan clock signal line 171, may have higher resistance by having a longer length than the first connection line 176_1 that connects the (n)th sixth transistor T6 (n) and the first scan clock signal line 171.

In addition, there occurs a resistance deviation caused by a difference in length between the third connection line 179_1 and the fourth connection line 179_2. That is, the fourth connection line 179_2, which connects the (n+3)th sixth transistor T6 (n+3) and the fourth scan clock signal line 171, may have higher resistance by having a longer length than the third connection line 179_1 that connects the (n+2)th sixth transistor T6 (n+2) and the third scan clock signal line 171.

Therefore, in the third exemplary aspect of the present disclosure, a compensation pattern 385 may be additionally formed on a side surface of the second connection line 176_2 and a side surface of the fourth connection line 179_2 that have higher resistance by having longer lengths. As a result, it is possible to cope with a line dim defect caused by a resistance deviation.

The compensation pattern 385 may be disposed between the wiring part WP and the circuit part CP spaced apart from the cathode 153 at a predetermined distance. However, the present disclosure is not limited thereto. A part of the compensation pattern 385 may also be disposed at the wiring part WP.

Meanwhile, the present disclosure may additionally provide an undercut provided between the wiring part WP and the circuit part CP and formed in a lower portion of the lower inner dam 181b. The undercut will be described in detail with reference to the drawings.

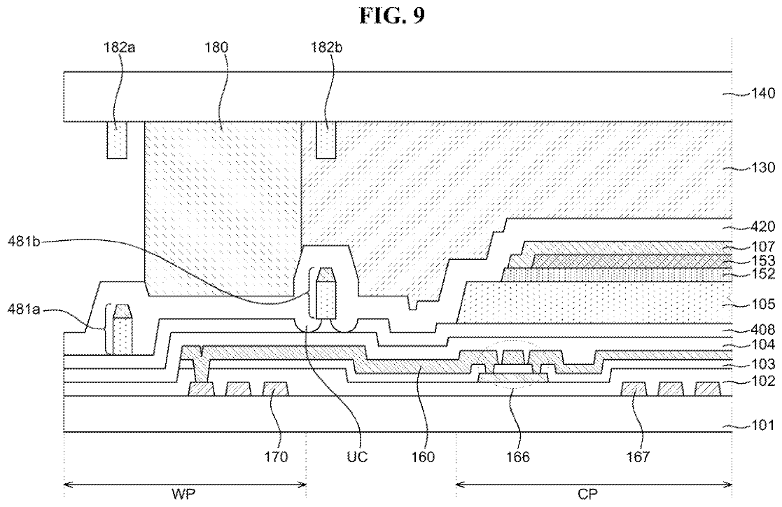

FIG. 9 is a view illustrating a part of a cross-sectional structure of a display panel according to a fourth exemplary aspect of the present disclosure.

The display panel according to the fourth exemplary aspect of the present disclosure in FIG. 9 is substantially identical in configuration to the display panel according to the first exemplary aspect in FIG. 6, except for a configuration of an undercut UC formed in a protective layer 408 formed below a lower inner dam 481b. Therefore, repeated descriptions of the identical components will be omitted.

FIG. 9 illustrates a cross-sectional structure of a part of the non-display area including the wiring part WP and the circuit part CP.

With reference to FIG. 9, the interlayer insulation layer 104, the protective layer 108, and the planarization layer 105 may be disposed on the upper portion of the first substrate 101.

Further, the dam 180 may be provided at the edge of the first substrate 101 and disposed between the first substrate 101 and the second substrate 140.

The dam 180 may be disposed at the wiring part WP in the non-display area. For example, the dam 180 may be disposed on a plane to surround the circuit part CP and the bonding film 130.

The dam 180 may be disposed to be spaced apart from the planarization layer 105 and the circuit part CP at a predetermined distance. Therefore, the dam 180 and the planarization layer 105 do not overlap each other, which may suppress cracks in the protective layer 120 that may be formed when the dam 180 and the planarization layer 105 are pushed.

The GIP signal/power line 170 may be disposed on the lower portion of the dam 180.

In addition, a plurality of lower dams 481a and 481b may be disposed on the upper portion of the wiring part WP in the non-display area.

For example, the lower dams 481a and 481b may include a lower outer dam 481a and a lower inner dam 481b. However, the present disclosure is not limited thereto.

For example, the lower inner dam 481b may be disposed on the protective layer 408 and disposed at one side of the dam 180, i.e., disposed inside the dam 180. Further, because the lower inner dam 481b is disposed inside the dam 180, the lower inner dam 481b may be disposed to be spaced apart from the GIP signal/power line 170 at a predetermined distance.

For example, the lower inner dam 481b may be disposed between the wiring part WP and the circuit part CP.

According to the fourth exemplary aspect of the present disclosure, the undercut UC may be formed in the protective layer 408 disposed below the lower inner dam 481b. The undercut UC may be provided as a plurality of undercuts UC.

The undercut UC may have an inversely tapered shape. The moisture penetration can be blocked by the undercut UC having the inversely tapered shape, thereby improving moisture transmission reliability.

The capping layer 107 and insulation layer 420 may be disposed on the cathode 153. For example, the insulation layer 420 may extend to the non-display area.

The insulation layer 420 may be disposed to cover the cathode 153 and the planarization layer 105.

The insulation layer 420 may extend to the wiring part WP to cover the lower dams 481a and 481b. For example, the insulation layer 420 may cover the undercut UC formed in the protective layer 408.

The exemplary aspects of the present disclosure may also be described as follows:

According to an aspect of the present disclosure, there is provided a display device. The display device comprises first and second substrates each divided into a display area and a non-display area, a dam disposed between the first and second substrates, a wiring part positioned in the non-display area of the first substrate to overlap the dam, a circuit part provided inside the dam, spaced apart from the wiring part, and positioned in the non-display area of the first substrate and a planarization layer disposed over the first substrate of the circuit part and spaced apart from the dam.

The display device may further include a light-emitting element disposed in the display area of the first substrate and including an anode, an organic layer, and a cathode.

The cathode may extend to the non-display area to cover the circuit part and may be disposed to be spaced apart from the wiring part.

The display device may further include a bonding film provided between the first substrate and the second substrate and disposed inside the dam.

The display device may further include a plurality of lines disposed on the wiring part and configured to transmit a signal or power, the plurality of lines may comprise a plurality of clock lines, a plurality of signal lines, and a plurality of high-potential power voltage lines.

The display device may further include a plurality of low-potential voltage lines disposed on the circuit part, the plurality of lines and the plurality of low-potential voltage lines may be disposed on the same layer.

The display device may further include a buffer layer disposed on the plurality of lines and the plurality of low-potential voltage lines, the buffer layer extends to the non-display area to cover the plurality of lines and the plurality of low-potential voltage lines.

The display device may further include a plurality of transistors disposed on the circuit part, the plurality of transistors may be electrically connected to the plurality of lines through a plurality of connection lines.

The plurality of connection lines may comprise a first connection line configured to connect one of the plurality of lines and one of the plurality of transistors and a second connection line configured to connect another of the plurality of lines and another of the plurality of transistors.

The second connection line may have a longer length than the first connection line, and a compensation pattern may be added to a side surface of the second connection line.

The compensation pattern may be spaced apart from the cathode at a predetermined distance.

The organic layer may be disposed on the planarization layer on the circuit part, the cathode may be disposed on the organic layer on the circuit part, and the organic layer and the cathode may be disposed to be spaced apart from an end of the planarization layer at a predetermined distance.

The cathode may be disposed inside the dam to cover only the circuit part.

The display device may further include a capping layer disposed on the cathode to cover the cathode, the capping layer may be disposed to be spaced apart from an end of the planarization layer at a predetermined distance.

The display device may further include a lower outer dam provided on an upper portion of the first substrate and disposed outside the dam and a lower inner dam disposed inside the dam.

The lower outer dam may overlap the wiring part, and the lower inner dam may be disposed to be spaced apart from the plurality of lines at a predetermined distance.

The display device may further include an insulation layer disposed on the capping layer, the insulation layer may extend to the non-display area to cover the lower outer dam and the lower inner dam.

The display device may further include an upper outer dam provided over the second substrate and disposed outside the dam, and an upper inner dam disposed inside the dam.

The upper outer dam and the upper inner dam may be respectively positioned to correspond to the lower outer dam and the lower inner dam.

The display device may further include an undercut formed in a lower portion of the lower inner dam, the insulation layer may fill the undercut.

Although the exemplary aspects of the present disclosure have been described in detail with reference to the accompanying drawings, the present disclosure is not limited thereto and may be embodied in many different forms without departing from the technical concept of the present disclosure. Therefore, the exemplary aspects of the present disclosure are provided for illustrative purposes only but not intended to limit the technical concept of the present disclosure. The scope of the technical concept of the present disclosure is not limited thereto. Therefore, it should be understood that the above-described exemplary aspects are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
first and second substrates each divided into a display area and a non-display area;
a dam disposed between the first and second substrates and surrounding the display area;
a wiring part positioned in the non-display area of the first substrate and overlapping the dam; and
a circuit part provided inside the dam, spaced apart from the wiring part, and positioned in the non-display area of the first substrate.

2. The display device of claim 1, wherein a cathode extends to the non-display area to cover the circuit part and is spaced apart from the wiring part.

3. The display device of claim 1, further comprising a bonding film provided between the first substrate and the second substrate and disposed inside the dam.

4. The display device of claim 1, wherein the wiring part is configured to transmit a signal or power and includes a plurality of clock lines, a plurality of signal lines, and a plurality of high-potential power voltage lines.

5. The display device of claim 4, further comprising a plurality of low-potential voltage lines disposed on the circuit part,
wherein the wiring part and the plurality of low-potential voltage lines are disposed on a same layer.

6. The display device of claim 5, further comprising a buffer layer disposed on the wiring part and the plurality of low-potential voltage lines,
wherein the buffer layer extends to the non-display area to cover the wiring part and the plurality of low-potential voltage lines.

7. The display device of claim 5, further comprising a plurality of transistors disposed on the circuit part,
wherein the plurality of transistors is electrically connected to the wiring part through a plurality of connection lines.

8. The display device of claim 7, wherein the plurality of connection lines comprises:
a first connection line connecting the wiring part and one of the plurality of transistors; and
a second connection line connecting the wiring part and another of the plurality of transistors.

9. The display device of claim 8, further comprising a compensation pattern added to a side surface of the second connection line,
wherein the second connection line has a longer length than the first connection line.

10. The display device of claim 9, wherein the compensation pattern is spaced apart from a cathode.

11. The display device of claim 2, wherein an organic layer is disposed on a planarization layer that is disposed on the circuit part,
wherein the cathode is disposed on the organic layer, and
wherein the organic layer and the cathode are spaced apart from an end of the planarization layer.

12. The display device of claim 2, wherein the cathode is disposed inside the dam to cover only the circuit part.

13. The display device of claim 11, further comprising a capping layer disposed on the cathode to cover the cathode,
wherein the capping layer is spaced apart from an end of the planarization layer.

14. The display device of claim 13, further comprising:
a lower outer dam provided on an upper portion of the first substrate and disposed outside the dam; and
a lower inner dam disposed inside the dam.

15. The display device of claim 14, wherein the lower outer dam overlaps the wiring part, and
wherein the lower inner dam is spaced apart from the wiring part.

16. The display device of claim 14, further comprising an insulation layer disposed on the capping layer,
wherein the insulation layer extends to the non-display area to cover the lower outer dam and the lower inner dam.

17. The display device of claim 14, further comprising an upper outer dam provided over the second substrate and disposed outside the dam, and an upper inner dam disposed inside the dam.

18. The display device of claim 16, further comprising an undercut in a lower portion of the lower inner dam,
wherein the insulation layer fills the undercut.

19. The display device of claim 1, further comprising a planarization layer disposed over the first substrate of the circuit part and spaced apart from the dam.

20. A display device comprising:
first and second substrates where a display area and a non-display area are defined;
a first dam disposed on the second substrate;
a wiring part disposed in the non-display area of the first substrate and overlapping the first dam;
a circuit part spaced apart from the wiring part, disposed in the non-display area of the first substrate and disposed at a side of the first dam closer to the display area; and
one or more second dam disposed in close proximity to the first dam at at least one of the first and second substrates.

21. The display device of claim 20, further comprising a cathode of a light-emitting element extending to the non-display area and overlapping the circuit part.

22. The display device of claim 21, wherein the cathode is disposed on the one or more second dam.

23. The display device of claim 20, further comprising an insulation layer disposed on the one or more second dam.

24. The display device of claim 23, further comprising an undercut portion in the insulation layer under the one or more second dam.

25. The display device of claim 20, further comprising a connection line electrically connecting the wiring part and the circuit part.

26. The display device of claim 20, further comprising a planarization layer disposed at the circuit part and not disposed at the wiring part.
